(19) United States
(12) Patent Application Publication
(10) Pub. No.: US 2018/0149606 A1
(43) Pub. Date: May 31, 2018

(54) XENON BASED DRUG PROTEIN BINDING ASSAY

(71) Applicant: The Regents of the University of California, Oakland, CA (US)

(72) Inventors: Muller Gomes, Berkeley, CA (US); Christophoros Vassiliou, Aradippov (CY); Alex Pines, Berkeley, CA (US)

(21) Appl. No.: 15/819,300

(22) Filed: Nov. 21, 2017

Related U.S. Application Data
(60) Provisional application No. 62/426,781, filed on Nov. 28, 2016.

(51) Int. Cl. G01N 24/08; G01R 33/50; G01R 33/563

(52) U.S. Cl. CPC G01N 24/088; G01R 33/56358; G01R 33/50

(57) ABSTRACT

Described herein is a technique and method for analyzing the protein binding affinity of a drug. The techniques and methods described herein leverage magnetic resonance techniques such as NMR and MRI to make relaxation measurements of an NMR detectable species. In some embodiments, a rubidium polarizer is used to magnetize ¹²⁹Xe, which is bubbled into a protein solution. The magnetic decay of the hyperpolarized ¹²⁹Xe is monitored by measuring the T1 or T2 of ¹²⁹Xe through NMR spectroscopy.

### RELATED APPLICATIONS

This application claims priority to U.S. Provisional Patent Application No. 62/426,781, filed Nov. 28, 2016, which is herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND

Blood proteins, such as albumin, contain many sites that bind many different molecules in the body, such as bilirubin. When bilirubin is bound by albumin, the free fraction of bilirubin is reduced, significantly lowering its toxicity. Blood protein binding sites also accept drug molecules. Drugs capable of binding to these sites are as diverse as the anticoagulant warfarin, the antibiotic flucloxacillin and the anesthetic propofol. It is widely believed that the potency of a drug depends on the free fraction of the drug—the amount present in the blood that is not bound to albumin or another protein. For example, it is thought that only the free fraction of flucloxacillin, is available to fight infection. Therefore, in order to predict the efficacy of a drug, it is necessary to know its affinity for the binding pockets of various blood proteins, albumin especially. The FDA requires that every drug list its protein-binding ratio for this reason.

### SUMMARY

Described herein are techniques and methods for measuring a compound's binding affinity for a protein. In some embodiments (e.g., see FIG. 2), the method comprises: providing a solution comprising the protein, the compound, and a hyperpolarized noble gas (205), and measuring a relaxation rate of the hyperpolarized noble gas (210). In some embodiments, disclosed is a method for measuring a compound's binding affinity for a protein. In some embodiments, measuring the magnetic resonance relaxation rate comprises applying a static magnetic field to the solution; applying a first radiofrequency pulse to the solution; applying at least a second radiofrequency pulse to the solution, wherein the second radiofrequency pulse is out of phase with the first pulse; and detecting a resonant response to the radiofrequency pulses. Some embodiments comprise repeating applying the second radiofrequency pulse and detecting the resonant response. Some embodiments comprise repeating applying the second radiofrequency pulse a plurality of times separated by a time less than 400 milliseconds (ms) and detecting a plurality of resonant responses. Some embodiments comprise determining the magnetic resonance relaxation rate from the plurality of detected resonant responses. In some embodiments, the static magnetic field has a strength higher than 8 T. In some embodiments, the static magnetic field has a strength lower than 2 T. In some embodiments, the static magnetic field has a strength lower than 2 T or higher than 8 T. In some embodiments, the first radiofrequency pulse is a 90 degree pulse. In some embodiments, the second radiofrequency pulse is a 180 degree pulse. In some embodiments, the first radiofrequency pulse is a pulse between 10 degrees and 45 degrees. In some embodiments, the second radiofrequency pulse is a pulse between 10 degrees and 45 degrees. In some embodiments, the second radiofrequency pulse is a 20 degree pulse.

In some embodiments, the protein is a blood protein. In some embodiments, the protein is selected from the group consisting of: albumin, globulin, transferrin, or a lipoprotein. In some embodiments, the protein is albumin. In some embodiments, the hyperpolarized noble gas is ¹²⁹Xe. In some embodiments, the hyperpolarized noble gas is ³He. In some embodiments, the hyperpolarized noble gas is ¹²⁹Xe or ³He. In some embodiments, the solution comprises an anti-foaming agent. In some embodiments, the anti-foaming agent is a C₂-C₁₀ alkanol. In some embodiments, the anti-foaming agent comprises at least one alcohol selected from the group consisting of: hexanol, septanol, octanol, nonanol, and decanol. In some embodiments, the compound is a drug molecule.

In some embodiments, the relaxation rate is measured using an alkali vapor magnetometer. In some embodiments, the relaxation rate is measured using a rubidium magnetometer. In some embodiments, the relaxation rate is measured using a potassium magnetometer. In some embodiments, the relaxation rate is measured using a cesium magnetometer. In some embodiments, the relaxation rate is measured using a pick up coil. In some embodiments, the relaxation rate is measured using an alkali vapor magnetometer or a pick up coil. In some embodiments, the relaxation rate includes at least one of: a longitudinal relaxation rate (T1), and a transverse relaxation rate (T2). Some embodiments comprise correlating the magnetic resonance relaxation rate with binding affinity. Some embodiments comprise generating a flow of hyperpolarized noble gas into the solution, and stopping the flow of hyperpolarized noble gas prior to measuring the magnetic resonance relaxation rate of the hyperpolarized noble gas in the solution.

Further described herein is a method of measuring the effects of different chemical environments on a compound's binding affinity for a protein (e.g., see FIG. 3), the method comprising providing a first solution comprising: the protein, the compound, a first concentration of an environment altering agent, and a hyperpolarized noble gas (305); measuring a first magnetic resonance relaxation rate of the hyperpolarized noble gas in the first solution (310); providing a second solution comprising: the protein, the compound, a second concentration of the environment altering agent, and the hyperpolarized noble gas (315); and measuring a second magnetic relaxation rate of the hyperpolarized noble gas in the second solution (320). In some embodiments, the second solution is obtained by adding an amount of the environment altering agent to the first solution. In some embodiments, the environment altering agent comprises at least one of: an acid, a base, a salt, or a drug molecule.

Further described herein is an apparatus for determining a compound's binding affinity for protein comprising a first syringe pump containing a first solution comprising the protein; a second syringe pump containing a second solution comprising the protein and a compound to be tested; a gas infusion cartridge, wherein outlets of the first and second syringe pumps are configured to permit injection of a mixture of the first and second solutions into the gas infusion cartridge; and an NMR spectrometer, wherein an outlet of gas infusion cartridge is configured to provide the mixture to the NMR spectrometer. Some embodiment comprise at least a third syringe pump, containing at least one of: an acid, a base, a salt, or a drug molecule. Some embodiments comprise an NMR tube having an anti-protein binding coating.

### BRIEF DESCRIPTION OF THE DRAWINGS

FIG. 1 shows an example apparatus for use in the techniques and methods described herein.

FIG. 2 shows an example of a flow diagram illustrating a method of measuring a compound's binding affinity for a protein.

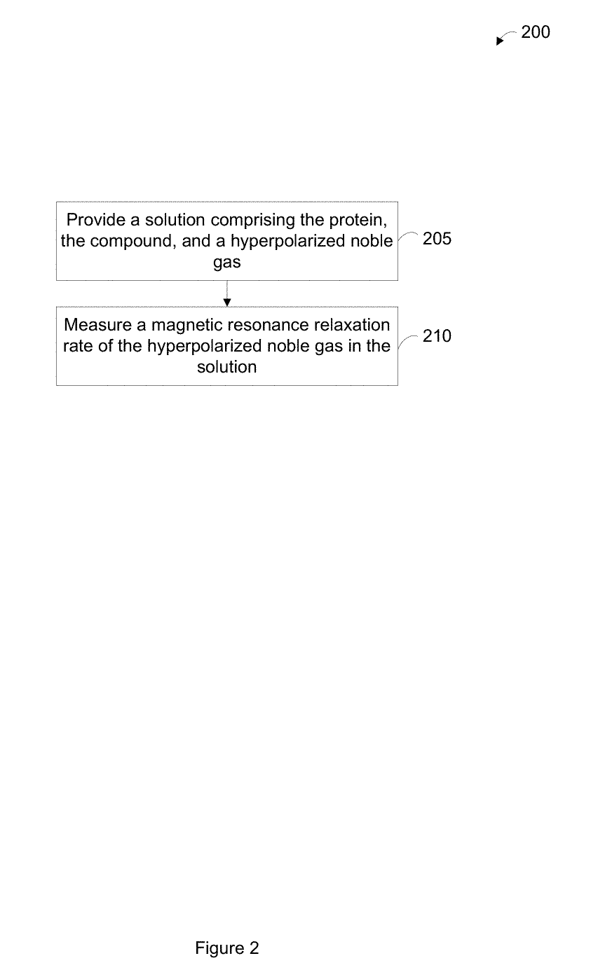

FIG. 3 shows an example of a flow diagram illustrating a method of measuring the effects of different chemical environments on a compound's binding affinity for a protein.

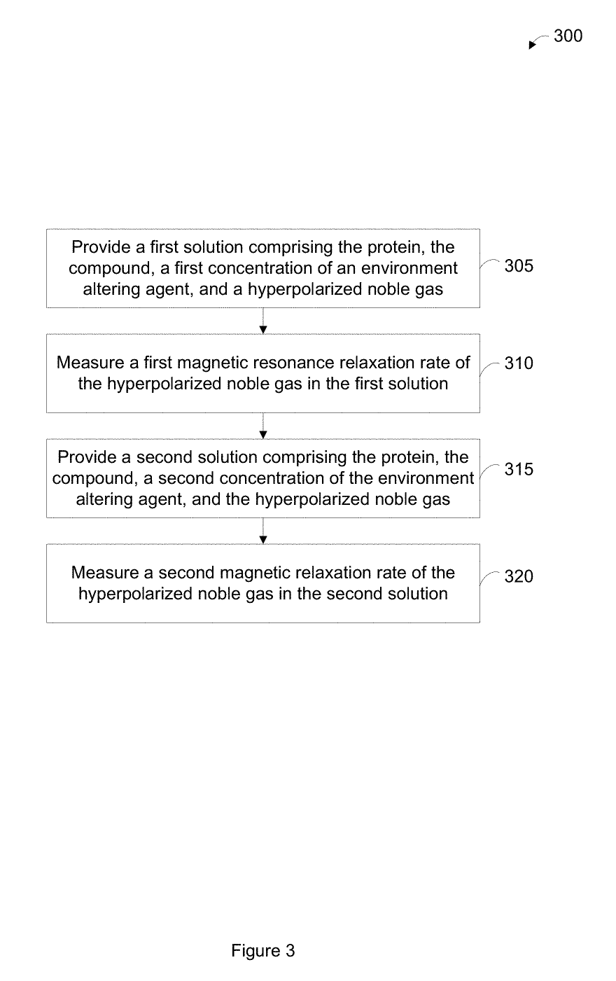

FIG. 4 shows examples of drug titration curves that show the change in xenon T₂ of a 10 μM solution of bovine serum albumin for three drugs.

FIG. 5 shows examples of drug titration curves that compare a strong binding drug, warfarin, to three drugs predicted to have lesser binding affinities.

FIG. 6 shows examples of drug titrations curves comparing warfarin and tenoxicam.

FIG. 7 shows an example of a scatter plot that shows how sodium oleate affects the bulk T₂ of xenon in a solution of 10 μM albumin.

FIG. 8 shows an example of a plot of the change in R₂ after 1 mM of a drug was added to 10 μM of BSA.

### DETAILED DESCRIPTION

Several methods exist for measuring the binding ratios of various blood proteins, such as albumin. However, these methods depend on either the natural fluorescence of some of albumin's binding pockets or rely on the use of membrane diffusion techniques. One such technique, the equilibrium dialysis method, is the most common method of testing a drug's protein binding affinity. Frequently referred to in the literature as the “gold standard” of protein binding experiments, this method utilizes a protein solution placed on one side of a membrane, and a drug solution placed on the other. The drug is able to traverse the membrane and bind to the protein in solution on the other side. The drug-protein solution is then removed, and the concentration of protein-bound drug is measured with high performance liquid chromatography. While useful and reliable, this method is slow. Furthermore, it is known that some fraction of the drug will inevitably bind the membrane, reducing the accuracy of this assay. These methods are also insensitive to potential interactions between drug molecules and the surface of proteins.

Like many small molecules, xenon is also capable of binding to blood protein pockets. When xenon is bound to these binding pockets, its magnetic resonance relaxation rate is higher than when it is not bound. The fraction of xenon bound by a protein's pockets can thus be measured by monitoring the relaxation rate of xenon to detect when it has been forced out of a binding pocket. While not being bound by any particular theory, there are several potential explanations for the faster relaxation rate of bound xenon. The higher relaxation rate might be due to the close proximity of many protein protons. It is also possible that xenon may move more slowly when bound by the protein, thereby increasing its magnetic resonance relaxation rate. Notably, the transverse relaxation rate may also be affected as xenon exchanges in and out of sites having different chemical shifts. For instance, when the xenon is perpendicular to the external magnetic field, and it is exchanging between two sites with different chemical shifts, it experiences a time dependent magnetic field in the same direction as the external magnetic field. This field fluctuates randomly, but is perpendicular to the quantization axis of the transverse xenon. Therefore, the field can induce relaxation, even if both the distance and correlation time of the two sites are the same. However, the field does scale with the strength of the external magnetic field, and provides a negligible contribution at very low fields, leaving only distance and correlation time as possible contributions.

Regardless of the mechanism, it is possible to measure the binding affinity of a drug for a protein by introducing a drug molecule of interest into a solution with hyperpolarized xenon and a target protein. The drug molecule will bind to the protein, thus preventing xenon from occupying the same binding site, or forcing xenon out of the binding site, depending on the affinity between the pharmaceutical product of interest and the target protein. These interactions will affect the magnetic resonance relaxation rate of xenon. Accordingly, by monitoring the change in relaxation rate of xenon as more of the drug is added to solution, it is possible to determine the affinity of the drug for target protein. Any protein that changes shape or contains a cavity can be studied using this method. Because this method relies on the interaction between xenon and protein surfaces or cavities, it is possible to more generally use this method to detect changes in the occupancy of protein cavities or even changes in the protein's conformation.

The affinity between protein surfaces and xenon significantly expands the possible utility of these techniques. While it is possible to base this technique solely on competitive binding to protein cavities, it is also possible to exploit the interaction between xenon and the protein surface. When proteins bind to small molecules or encounter a new environment, they may undergo a conformational change. This change will affect the surface of the protein in many possible ways. A conformational change could alter the amount of amino acids exposed to the surface or it could alter the kind of amino acids exposed to the surface. Magnetic resonance relaxation measurements of hyperpolarized xenon are potentially sensitive to either of these changes for the following reasons. Xenon has a weak affinity with all amino acids, and directly probes the surface and pockets of proteins. Thus, xenon is useful to detect a conformation change or a drug binding cavity. If a protein changes in a way that exposes more of its amino acids to solution, then this change can be detected because xenon will bind to the newly exposed amino acids. Once bound, the magnetic resonance relaxation rate will be detectably increased. Alternatively, a protein's conformational change can alter the composition of surface amino acids without significantly altering their number. This can also be detected because xenon will bind to some amino acids with more affinity than others.

Described herein are techniques and methods for analyzing a drug molecule's protein binding affinity. The techniques and methods described herein leverage magnetic resonance techniques, such as NMR, to make relaxation measurements of an NMR detectable species. Unlike techniques currently in use, the techniques and methods described herein are rapid, efficient, and more sensitive than those known in the art.

The techniques and methods described herein are applicable to a wide variety of biomolecules, including blood proteins, globulin proteins, and lipoproteins. Some exemplary proteins include albumin and transferrin. Advantageously, the techniques and methods described herein are able to utilize a wide variety of NMR detectable species, in addition to xenon. In some embodiments, the NMR detectable species is a noble gas such as helium, neon, argon, krypton, xenon, radon, and mixtures thereof. In some embodiments, the NMR detectable species is hyperpolarized. In some embodiments, the NMR detectable species is hyperpolarized ¹²⁹Xe. In some embodiments, the hyperpolarized gas is ³He.

Unlike transport-based tests that require long equilibration times, the protein changes measured by the techniques and methods described herein occur on a much faster timescale. By monitoring the rate of decay of the xenon peak, the drug's affinity for protein can be determined. The rapid measurement performed directly in solution enables high-throughput, automated protein titration and analysis.

In some embodiments, the techniques and methods described herein involve using a solution containing the drug, the protein and an NMR detectable species, such as hyperpolarized xenon, although other noble gasses may be used. In some embodiments, xenon is hyperpolarized via optical pumping in a rubidium polarizer, although potassium and cesium hyperpolarizes may be suitable as well. The hyperpolarized xenon can then be bubbled into an NMR tube containing the drug-protein solution, and the magnetic resonance relaxation rate of xenon can be monitored in whatever way is most convenient to the user. For instance, in some embodiments, NMR machines utilizing high field magnets are used to determine the transverse relaxation rate (T2) of xenon as a function of drug concentration. In various embodiments, high field magnets are used to generate a magnetic field higher than 6 Tesla, higher than 8 Tesla, higher than 10 Tesla, between 4 and 12 Tesla, between 8 and 11 Tesla, between 9 and 10 Tesla, or about 9.4 Tesla. In some embodiments, NMR machines utilizing low field magnets are used to determine the longitudinal relaxation rate (T1) of xenon. In various embodiments, low field magnets are used to generate a magnetic field lower than 3 Tesla, lower than 2 Tesla, lower than 1 Tesla, between 1 and 2 Tesla, or about 1.1 Tesla. In some embodiments, low field magnets can be used to generate magnetic fields on the order of earth's field. In some embodiments, low field magnets are used to generate magnetic fields lower than 100 mT, lower than 80 mT, lower than 50 mT, lower than 25 mT, lower than 10 mT, between 1 mT and 20 mT, between 5 mT and 20 mT, or about 10 mT. In some embodiments, low field magnets on the order of earth's field are used to generate magnetic fields lower than 1 mT, lower than 0.5 mT, lower than 0.25 mT, lower than 0.1 mT, lower than 0.06 mT, lower than 0.02 mT, between 0.02 mT and 0.1 mT, or about 0.05 mT. When utilizing low field NMR machines, the T1 relaxation rate can be determined by using low field magnetometers, such as an atomic vapor magnetometer or a SQUID magnetometer, to directly measure the magnetic field. In such embodiments, techniques known in the art for detecting nuclear magnetic resonance with a magnetometer can be used. For example, transverse magnetic field pulses may be utilized.

In some embodiments, T2 is measured by using a CPMG pulse sequence. For example, an initial 90 degree excitation pulse is applied followed by a series of 180 degree pulses that are out of phase with the excitation pulse. The resulting echoes are detected and the decay in the signal is measured to determine T2 (e.g., by fitting the signal decay to an exponential function). In some embodiments, the 180 degree pulses following the initial excitation pulse are repeated until the magnetization of xenon has decayed substantially. In some embodiments, the minimum number of pulses to be delivered can be determined by multiplying T2 by 5, and dividing the product by the echo spacing in seconds. For instance, if the T2 is one second and the echo spacing is 0.1 seconds, then the minimum number of 180 degree pulses would be 50. However, it can be advantageous to perform at least twice as many measurements to ensure that the signal has decayed completely.

In various embodiments, the time between 180 degree pulses can be less than 400 ms, less than 300 ms, less than 250 ms, between 50 ms and 400 ms, between 100 ms and 300 ms, between 150 ms and 250 ms, or about 200 ms. It is also possible to measure T1 at high magnetic fields, by delivering a series of 20 degree pulses and measuring the rate of decay of the detected signal.

It will be appreciated that the T1 or T2 relaxation of xenon may be measured using any of a variety of techniques that are known in the art. The methods herein are not limited by the specific techniques described above. For instance, in some embodiments, the initial pulse may be a pulse between 10 and 45 degrees, followed by a series of subsequent 10 to 45 degree pulses that are out of phase with the excitation pulse.

Hyperpolarization of xenon, or other appropriate species, may be achieved through a variety of techniques known to those skilled in the art. One possible hyperpolarization technique is spin-exchange optical pumping. This process utilizes a circularly polarized laser, tuned to a transition frequency of an alkali vapor, to excite and spin-polarize the electron spin of vaporized alkali metal atoms. Rubidium is commonly used, but other alkali metals including potassium and cesium are suitable. Subsequent spin-exchange collisions between the polarized alkali metal atoms and xenon transfer the electron spin polarization of the alkali metal vapor to the nuclei of xenon, thereby producing hyperpolarized xenon. Other species suitable for hyperpolarization and protein-affinity analysis, in accordance with the techniques and methods described herein, include ¹H, ³He, ¹³C, ⁸³Kr, and ¹²⁹Xe, among others. Hyperpolarized gasses may be introduced into a test solution via bubbling, infusion cartridges, membrane infusion, or any other convenient means. In some embodiments, it can be advantageous to halt the flow of hyperpolarized gas to allow the solution to homogenize before performing a measurement. In some embodiments, hyperpolarized xenon is bubbled into a test solution using an infusion cartridge, and the flow of xenon is halted prior to performing a measurement.

In various embodiments of the techniques and methods described herein, hyperpolarized xenon is bubbled into a test solution comprising at least one protein of interest and at least one drug molecule. Suitable solutions can be prepared in a variety of manners. For instance, in some embodiments, an aqueous solution comprising a protein of interest is prepared. Suitable proteins include albumin, transferrin, globulin, lipoproteins, prothrombin, and glycoproteins, among others. In some embodiments, the protein is isolated from a whole blood sample. In various embodiments, the concentration of protein can be greater than 0.1 μM, greater than 0.2 μM, greater than 0.4 μM, greater than 0.8 μM, greater than 1 uM, greater than 2 μM, less than 5 μM, less than 2 μM, less than 1 μM, between 0.5 μM and 1.5 μM, and about 1 μM. In some embodiments, the concentration of protein can be substantially greater. For instance, in some embodiments, the concentration of protein may range from approximately 100 μM to 3,000 μM, from 200 μM to 200 μM, from 500 μM to 1500 μM, or about 700 μM. In some embodiments, a drug molecule of interest can be dissolved in the aqueous protein solution. Some example drug molecules include caffeine and flucloxacillin, though it will be apparent to one of skill in the art that additional drug molecules can be used. The concentration of drug molecule can vary widely, and may be dependent on the solubility limit of the drug molecule of interest. For instance, in some embodiments, the concentration of caffeine may be less than 16 μM, less than 40 μM, less than 80 μM, less than 100 μM, less than 1000 μM, less than 5000 μM, less than 10,000 μM, between 10,000 μM and 80,000 μM, greater than 80,000 μM, or any value therein. By way of example, the concentration of flucloxacillin may range from less than 50 μM, less than 100 μM, less than 200 μM, less than 500 μM, less than 1,000 μM, between 1,000 μM and 2,000 μM, greater than 2,000 μM, or any value therein.

In some embodiments, it can be advantageous to incorporate additional agents capable of altering the chemical dynamics of the solution. For instance, acids, bases, buffers, salts, ions, and other agents can be added to the solution for stability or to determine the effect of different chemical environments on a drug's protein affinity. Example acids include: Lewis acids, Bronsted-Lowry acids, strong acids, and weak acids, including HCl, NaOH, H₂SO₄, HNO₃, KOH, H₂CO₃, H₃BO₃, Mg(OH)₂, H₃PO₄, NH₄OH, and HC₂H₃O₂, among others. Example bases include LiOH, NaOH, KOH, RbOH, NaNH₂, among others. Example buffers include Na₂CO₃, Na₂HPO₄, and KH₂PO₄, among others. Example salts include: NaCl, NH₄Cl, KCl, KBr, KI, and CaCl₂ among others. Example ions include CN⁻. NO₃⁻, OH⁻, SO₄⁻², NH₄⁺, H⁺, Cl⁻, and I⁻, among others. Other suitable agents include anti-foaming agents.

In some embodiments, an anti-foaming agent is included in the solution. Such an agent can prevent or minimize foam formation while bubbling xenon into the solution. While a wide variety of anti-foaming agents can be used, some anti-foaming agents may affect the xenon magnetic resonance relaxation rate. Thus, in some embodiments, an anti-foaming agent is selected that does not significantly alter the magnetic resonance relaxation rate of xenon in solution. In some embodiments, the anti-foaming agent is selected from pentanol, hexanol, septanol, octonal, nonanol, and decanol. In various embodiments, the concentration of anti-foaming agent is greater than 0.1 μL/L, greater than 0.25 μL/L, greater than 50 μL/L, greater than 1 μL/L, greater than 2 μL/L, greater than 5 μL/L, less than 10 μL/L, between 0.5 μL/L and 1.5 μL/L or about 1 μL/L.

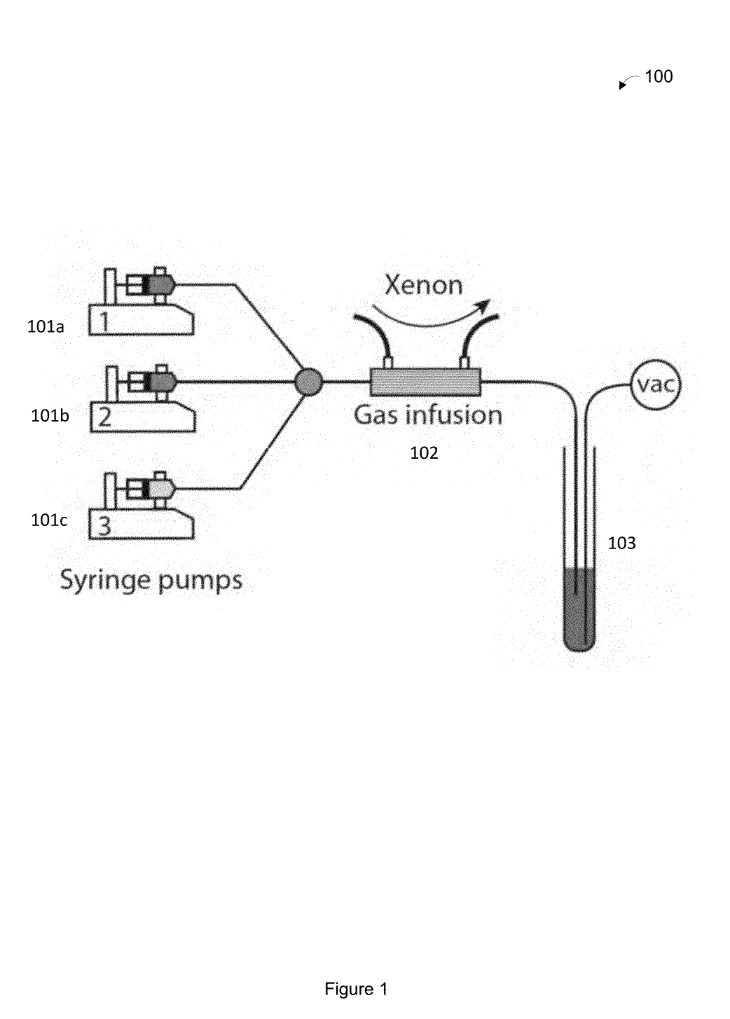

FIG. 1 depicts an example of an apparatus suitable for employing the techniques and methods disclosed herein. FIG. 1 depicts a plurality of syringe pumps 101a, 101b, and 101c in fluid communication with a gas infusion cartridge 102 and test tube 103. In some embodiments, the test tube may reside within an NMR machine, magnetometer, or other magnetic field detection means. In some embodiments, one syringe of the plurality of syringes 101a, 101b, and 101c may contain a drug of interest, dissolved to its solubility limit. A second syringe of the plurality of syringes 101a, 101b, and 101c may contain an aqueous protein solution. Using the plurality of syringes 101a, 101b, and 101c, it is possible to adjust the mixtures of the two solutions to create solutions of varying drug concentrations. In some embodiments, the mixed-solution is allowed to quickly equilibrate before it is passed through a gas infusion cartridge 102. The gas infusion cartridge 102 allows the operator to bubble in the desired concentration of hyperpolarized gas. The solution may then be injected directly into a suitable container, such as a test tube 103 residing in a NMR spectrometer, or other magnetic field detection means. In some embodiments, hyperpolarized xenon can be infused from a rubidium polarizer external to a NMR spectrometer. It is thus possible to measure the relaxation time of the hyperpolarized gas immediately and then the tube can be evacuated and prepared for the next sample allowing for rapid and efficient analysis.

While an apparatus comprising two-pumps as described above may be appropriate for studying drug-protein binding constants, additional pumps, such as is depicted in FIG. 1, may be added. Examples include adding a second or third drug to investigate drug interactions at the protein level, adjusting the solution pH, or changing salt concentrations. However, additional chemical environments can be studied as well. The parameters and contents of each syringe may vary based on the drugs being tested to mimic the clinically-relevant conditions in the body.

With such a fast, high throughput device available, it becomes possible to study many complicated drug protein interactions that require too many samples to be studied efficiently with conventional techniques. For instance, many drugs bind to the same albumin binding pockets. As such, drugs which bind to the same pocket may interfere with one another when taken simultaneously. Where one drug forces another out of an albumin binding pocket, the free fraction of the weaker binding drug would be greater than expected. This would amount to a greater effective dose of the drug, which could be very dangerous if unforeseen. Using the techniques and methods described herein, it is possible to determine such specific characteristics of protein-drug binding events. For instance, it is possible that the two binding pockets of albumin have different effects on the T2 of xenon. Thus, the techniques and methods described herein could be used to determine which pocket a drug binds to avoid such unforeseen interactions.

### Examples

The following examples are intended to be examples of the embodiments disclosed herein, and are not intended to be limiting.

The binding affinity between caffeine and albumin was measured according to the techniques described herein.

TABLE 1

| Concentration of Caffeine (μM) | Xenon relaxation time, T2 (s) |
|---|---|
| 0 | 0.48 ± 0.02 |
| 16 | 0.54 ± 0.04 |
| 43 | 0.47 ± 0.04 |
| 56 | 0.63 ± 0.04 |
| 100 | 0.69 ± 0.03 |
| 500 | 0.51 ± 0.03 |
| 5000 | 0.67 ± 0.04 |
| 80000 | 1.07 ± 0.03 |

Solutions were prepared comprising 10 μM albumin, and varying concentrations of caffeine as shown in Table 1. Hyperpolarized ¹²⁹Xe was generated in a rubidium cell hyperpolarizer, and bubbled into the solution. After saturation with xenon, the supply was turned off and the T2 of the hyperpolarized ¹²⁹Xe was then determined in an NMR machine at a magnetic field strength of 9.4 T. The resulting T2 relaxation time as a function of caffeine concentration is shown in Table 1.

The binding affinity between flucloxacillin and albumin was measured according to the techniques described herein.

TABLE 2

| Concentration of Flucloxacillin (μM) | T2 |
|---|---|
| 0 | 0.91 ± 0.04 |
| 70 | 0.91 ± 0.04 |
| 200 | 0.99 ± 0.04 |
| 250 | 1.53 ± 0.05 |
| 450 | 0.97 ± 0.03 |
| 2000 | 0.73 ± 0.04 |

Solutions were prepared comprising 10 μM albumin, and varying concentrations of flucloxacillin as shown in Table 2. Hyperpolarized ¹²⁹Xe was magnetized in a rubidium cell hyperpolarizer, and bubbled into the solution. After saturation with xenon, the supply was turned off and the T2 of the hyperpolarized ¹²⁹Xe was then determined in an NMR machine at magnetic field strength of 9.4 T. The resulting T2 relaxation time as a function of flucloxacillin concentration is shown in Table 2.

The following experiments were performed with fatty acid free bovine serum albumin. It is important to note whether the albumin one uses contains fatty acids both because the fats will alter the binding affinity of a drug and also because they alter the relaxivity of albumin. The drug titrations were performed by preparing a 10 μM solution of bovine serum albumin into which aliquots of high concentration drug solutions were added. Most drugs, as well as all protein solutions, were dissolved in 1×PBS buffer. It is important to keep the pH of the solution constant when studying albumin because that protein has many different pH dependent conformations. Some drugs, like tenoxicam, were not soluble in water, so they were instead dissolved in DMSO.

All solutions were made by dissolving the drugs in 1×PBS, with the exception of the tenoxicam solution. The T₂ times of solutions containing high concentrations of drugs were measured. These measurements revealed that the drugs themselves have a weak effect on the bulk T₂ of xenon. Another important result of these background studies is that DMSO does not bring down the T₂ of xenon significantly. For the tenoxicam solution, about 400 μL of DMSO was added to a 10 mL solution of 1×PBS. This only lowered the T₂ of the solution from 60 seconds to 40 seconds. This means that, used sparingly, DMSO can be used to dissolve water insoluble drugs for this method.

T₂ times were measured using a standard CPMG pulse sequence with 100 ms long echo spacings. All experiments were performed at 9.4 Tesla using hyperpolarized xenon. This hyperpolarized xenon was prepared using a homebuilt spin exchange optical pumping based polarizer. The protein solution was attached to the polarizer's flow system and the pressurized to 60 psi. Xenon was bubbled into the protein solution at a rate of about 0.1 standard liters per minute. The gas mixture used contained 2% xenon, with the rest of the gases being helium and nitrogen. All experiments were performed at 25 degrees Celsius.

All protein solutions required the addition of an antifoaming agent in order to prevent the xenon from forcing the sample out of the NMR tube. These experiments required xenon to be bubbled into the same protein solutions multiple times, resulting in a column of foam forming in the tube after every experiment. It could take several minutes or even hours for the foam to dissipate, so it was necessary to introduce an antifoaming agent to prevent it from forming. 1-octanol was used as the antifoaming agent in this experiment. The concentration of 1-octanol used was 5 μL of alcohol per 10 mL of solution. Commercially available agents tended to alter the T₂ of xenon too much to be useful.

Six drugs were studied with this new method. The drugs chosen were: warfarin, tenoxicam, flucloxacillin, caffeine, sodium salicylate, and minoxidil. These drugs bind with different strengths and they are also known to target different parts of albumin. The affinity of these drugs for albumin is shown in Table 3. Albumin is known to have two drug binding pockets: site 1 and site 2. Site 1 is supposed to bind warfarin, tenoxicam, and sodium salicylate and site 2 binds the other three drugs.

TABLE 3

| Ligand | Highest Binding Affinity log₁₀(Kₐ) |
|---|---|
| Warfarin | 6.8 |
| Flucloxacillin | 4.6 |
| Caffeine | 4.3 |
| Tenoxicam | 5.4 |
| Salicylate | 5.3 |
| Minoxidil | 0.7 |
| Oleate | 8.0 |

Table 3 shows the binding affinity of the ligands of interest for albumin. The binding affinity of a ligand for albumin can vary dramatically depending on the presence of fatty acids in solution, the temperature, and the species that provided the albumin. Whenever possible, the binding affinities chosen for this table were for the ligand binding to bovine serum albumin instead of other varieties of albumin at temperatures close to 25 degrees Celsius. Some of these ligands bind to multiple binding pockets, and so have more than one binding affinity. In those cases, the highest binding affinity was chosen.

The effect of these drugs on the T₂ of xenon was surprising. Instead of blocking the binding site and increasing the relaxation time, like in previous experiments, the T₂ dropped as more of the drugs were added. Warfarin, tenoxicam, and sodium salicylate reduced the xenon T₂ of albumin. Minoxidil, flucloxacillin, and caffeine had a much weaker effect on T₂. None of the drugs consistently increased the T₂ of xenon. Unfortunately, their effect on T₁ was not measured because the protein concentrations used were too low and because the external magnetic field was too high. Experiments where proteins drastically lowered the T₁ of xenon were performed at clinical fields of 1.5 Tesla, much lower than the fields used in this experiment.

The first thing to consider is that the drugs themselves are responsible for the drop in T₂. So, solutions containing high concentrations of the drug were prepared and studied. At concentrations several times those used in the titration experiments, the T₂ of the solutions remained above 20 seconds. The concentrations chosen for the drug were those close to their saturation point. Results from this experiment are summarized in Table 4.

TABLE 4

| Drug | Concentration (M) | T₂ (s) |
|---|---|---|
| Tenoxicam | 0.05 | 41 ± 1 |
| Salicylate | 0.0014 | 50 ± 1 |
| Caffeine | 0.057 | 25.8 ± 0.2 |
| Flucloxacillin | 0.0021 | 43 ± 1 |
| Warfarin | 0.00303 | 47 ± 2 |
| Minoxidil | 0.010 | 35.3 ± 0.4 |
| Sodium Oleate | 0.00003 | 34 ± 1 |

Table 4 shows the relaxation times of xenon in solutions with a high concentration of drugs. These data at least show that the decrease in T₂ is likely not due to the presence of the drug alone. This suggests that the interaction between the drug and the protein is responsible for the change in the xenon T₂. Since the T₂ of xenon does not increase with the addition of the drugs, this suggests that the gas can still access its binding pockets. This at least rules out competitive binding.

It is possible that the drugs make the protein more accessible to xenon, a form of cooperative binding. Such an effect has some precedence in the literature. Early work on protein binding noted that some drugs would increase the binding affinity of other drugs. The various binding pockets found on albumin are coupled together, allowing for more types of interactions between drugs besides competitive binding. It could be that something similar is occurring with xenon, where the binding of one drug increases the affinity of xenon for albumin by altering the conformation of the xenon binding sites. This change in the xenon binding sites makes it more likely to accept xenon.

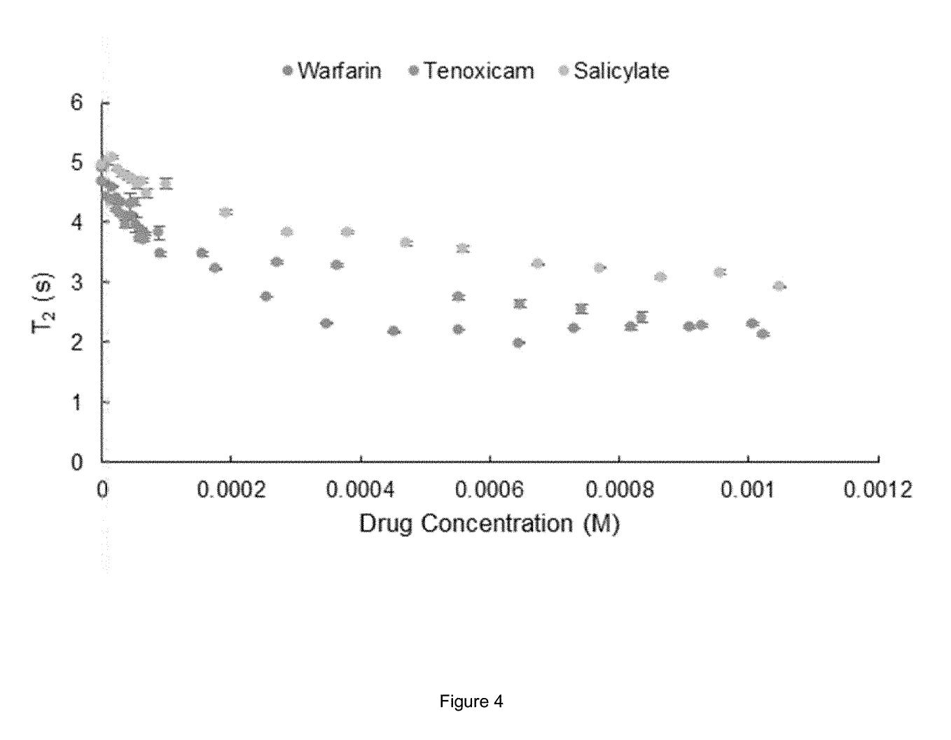

There are considerable differences in the behavior of the various drugs studied, as seen in FIGS. 4-6. Drugs that were supposed to bind the site 1, warfarin, tenoxicam, and sodium salicylate, changed T₂ more dramatically than other drugs, with the exception of caffeine. It is important to note that fluorescence experiments have confirmed that xenon interacts with site 1 because it quenches the fluorescence of a tryptophan at that site.

FIG. 4 shows examples of drug titration curves that show the change in xenon T₂ of a 10 μM solution of bovine serum albumin for three drugs. The three drugs chosen were sodium warfarin, sodium salicylate, and tenoxicam. Of the three, warfarin had the greatest effect, bringing the xenon T₂ of the albumin solution down to 2 seconds from about 5 seconds with only 300 μM of drug. However, the tenoxicam curve intersects the warfarin curve at 1 mM of drug. Salicylate also had a strong effect on the T₂ of the solution, but much less than the other two. This result is similar to what one sees in the literature, which states that tenoxicam and warfarin have a strong affinity for albumin, with salicylate having a lesser affinity

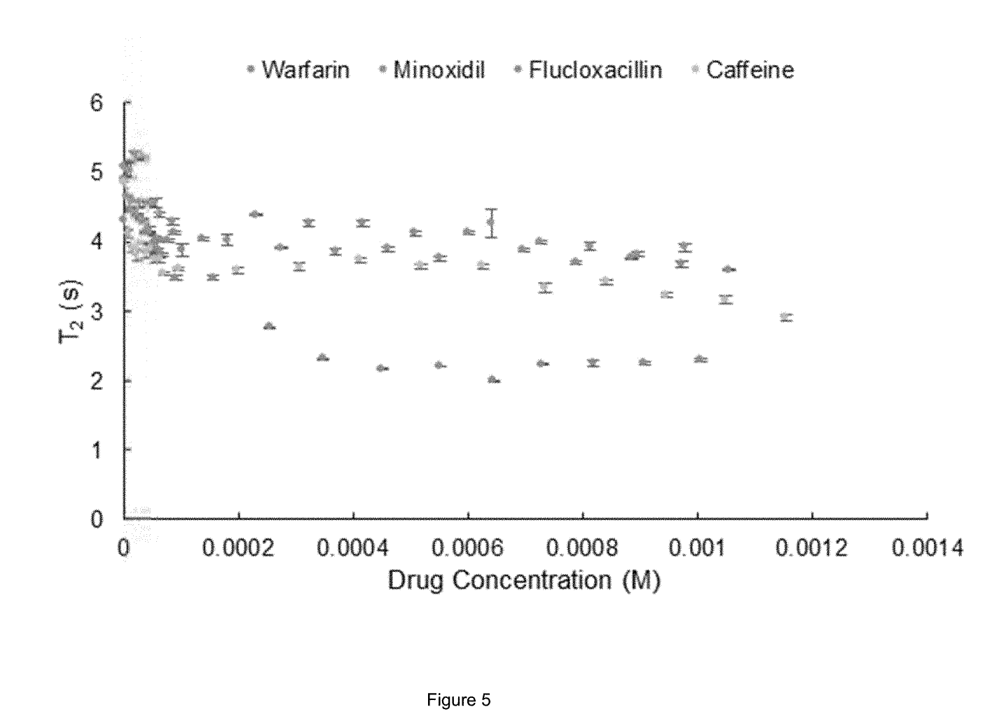

FIG. 5 shows examples of drug titration curves that compare a strong binding drug, warfarin, to three drugs predicted to have lesser binding affinities. Drugs with weaker binding affinities show inconsistent results, and tend to quickly level off at relatively high T₂ relaxation times.

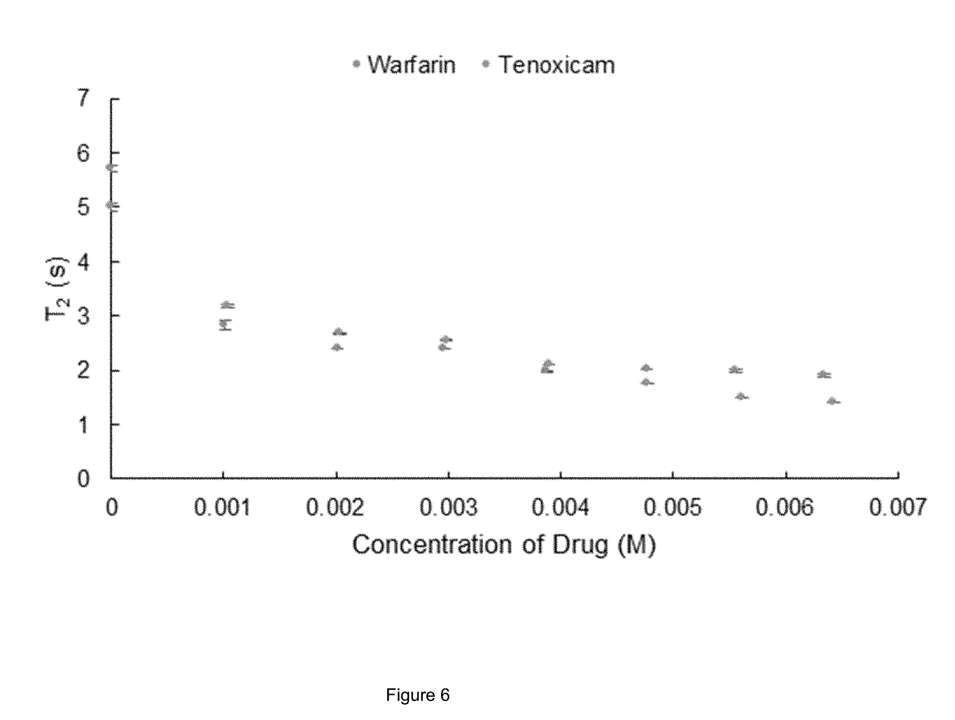

FIG. 6 shows examples of drug titrations curves comparing warfarin and tenoxicam. These curves go beyond the concentrations shown in FIGS. 4 and 5. Like before, the warfarin brings the T₂ of xenon down more rapidly but stops having much of an effect, while tenoxicam continues to lower the xenon T₂ for the entire experiment.

Of the three site 1 drugs, only the warfarin titration curve stopped changing after reaching a specific concentration. The other two site 1 drugs continued to affect the T₂ of xenon for the entire titration curve until reaching a concentration of 1 mM, the end of the titration. This experiment was repeated with higher concentrations of drug. In that experiment warfarin once again plateaued quickly. Sodium salicylate showed little change during the experiment and tenoxicam continued to decrease the xenon T₂ of the albumin solution until the end of the titration experiment. Perhaps the lack of a plateau is due to the presence of more binding sites. Flucloxacillin and minoxidil had no effect and caffeine had a mild effect.

Albumin also contains fatty acid binding sites, which are separate from the drug binding sites looked at previously. These fatty acid binding sites help solubilize the fatty acids in the blood, allowing for more fat to be present in serum than can dissolve in water. Fatty acids bind to albumin with much greater affinity than drugs, with the highest affinity sites binding with an affinity about three orders of magnitude greater than warfarin. The effect of these fatty acids on the relaxation of xenon were tested.

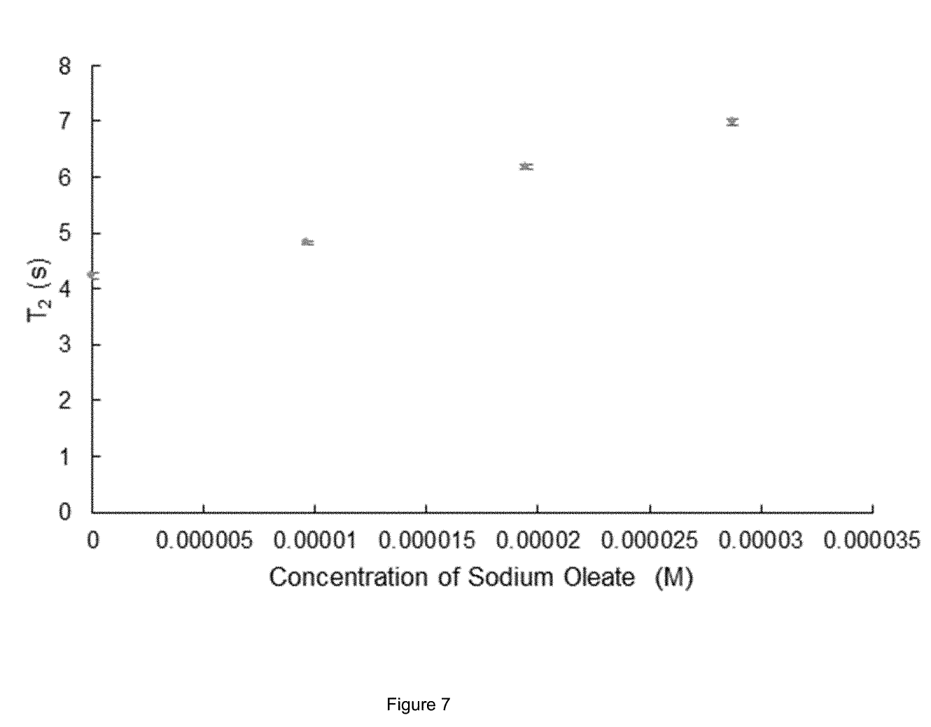

Unlike the drugs, fatty acids increase the T₂ of xenon, as shown in FIG. 7. FIG. 7 shows an example of a scatter plot that shows how sodium oleate affects the bulk T₂ of xenon in a solution of 10 μM albumin. Unique among the ligands studied in this experiment, sodium oleate increased the T₂ of xenon when added to solution. This suggests that this fatty acid was able to prevent xenon from interacting with albumin, perhaps by occupying a lipophilic site on the protein.

In this case, the mechanism for this change in relaxation is likely blocking. When a fatty acid is introduced into solution, it occupies the binding pocket, preventing xenon from interacting with it. This decreases the relaxivity of the albumin. It is not surprising that xenon binds to the fatty acid binding site. Xenon is lipophilic, making it likely to bind to the parts of albumin that bind fats. Also, computational studies have shown that xenon will bind to a site known to accept anesthesia molecules like enflurane. This binding site is close to one of the lipid binding sites. The T₂ times of xenon increases by 3 seconds after adding three times as much sodium oleate as albumin.

Analyzing T₂ relaxation data can be difficult because of the many possible contributions to any change in relaxation. The presence of multiple possible xenon binding sites also complicates analysis. Nevertheless, trying to get some understanding of T₂ relaxation is worthwhile because of its sensitivity to changes in the albumin. Performing similar experiments by measuring T₁ would require high protein concentrations and also low field spectrometers. A preliminary discussion of the contributions to T₂ is presented below.

There are broadly two categories of contributions to T₂ that will be considered here. The two contributions are the rapid relaxation of xenon bound to a slowly rotating protein and chemical exchange from a site with a unique chemical shift. Both of these contributions could plausibly be responsible for the change in T₂ times discussed herein.

Changes in the rotational dynamics of xenon will be discussed first. When xenon binds to albumin, its dynamics are likely slowed down dramatically. Such a change would explain the change in T₁ times seen in previous experiments done at clinical fields. Similar changes in dynamics are seen in experiments done on water and albumin. Like xenon, water also binds to albumin. Known as buried water, these bound water molecules exchange slowly enough for the rotational correlation time of water to be changed by this binding. However, both the T₁ times of xenon and water only change in response to changes in rotational correlation times at lower fields. T₂, however, responds to changes in correlation times at all fields.

With this in mind, a dipolar coupling based mechanism for the changes induced by the ligands studied can be proposed. The first thing that must be stated is that it is unlikely that the drug altered the rotational correlation time of the xenon bound to albumin. Albumin is a 66 kDa protein and most of the drugs studied in this paper have a molecular weight less than 500 Da. This suggests that the binding of a drug to albumin has a small effect on the rotational correlation time of the protein, which implies that the rotational correlation of the xenon bound to the protein also barely changes. Instead, the drug alters the sites occupied by xenon. The exact nature of this change is difficult to predict without a field cycling experiment. It might be possible that the xenon binding pockets bind xenon more tightly once the drug pocket becomes occupied. A more tight binding can affect relaxation in many different ways.

Occupying the drug-binding pocket can affect relaxation by changing the exchange time of the xenon bound to albumin. Keeping this discussion centered on dipolar coupling, a decrease in the exchange time would lower the T₂ of xenon, assuming that the bound relaxation time is short compared to the exchange time. Such a short bound relaxation rate is plausible. The exchange times one can expect are in the microsecond regime as are the bound xenon relaxation times, assuming that xenon rotates with the correlation time of albumin and is about an angstrom away from a nearby proton. Whether this calculated relaxation is accurate is difficult to predict, but it is at least plausible.

With that in mind, if the main contribution to xenon relaxation is chemical exchange, then an increase in the exchange time would be responsible for a drop in the xenon relaxation time. The exchange contribution to T₂ increases linearly with respect to the chemical exchange time in the fast exchange regime. This would suggest that the drug binding to albumin increases the exchange time of xenon. This would be the opposite of the change needed if one assumes that the rapid relaxation of bound xenon is responsible for the changes seen. As mentioned before, if a change in bound relaxation is needed to explain the changes in T₂ observed in this experiment, and that change was assumed to be related to the exchange time, then the exchange time would need to decrease. This would allow the rapidly relaxing bound pool to more rapidly mix with the slowly relaxing unbound pool. A change in the chemical exchange time in either direction could plausibly explain the changes in the T₂ times of xenon observed in this experiment. Figuring out which change, if any, is responsible would require field cycling experiments that could not be performed with the available equipment.

The results from these experiments are promising. So far, the binding between drugs with strong affinities, such as tenoxicam and warfarin, has been shown to be detectable with xenon relaxometry. Drugs that bind more weakly, like flucloxacillin and caffeine, have also been shown to affect the T₂ of xenon, but not as consistently. These experiments would need to be made more reproducible to measure the effects of drugs that weakly interact with albumin. If developed further, this method could become a useful tool for probing the interactions between a wide variety of ligands and proteins. The mechanism responsible for these changes in relaxation could be discovered by measuring relaxation times at multiple fields.

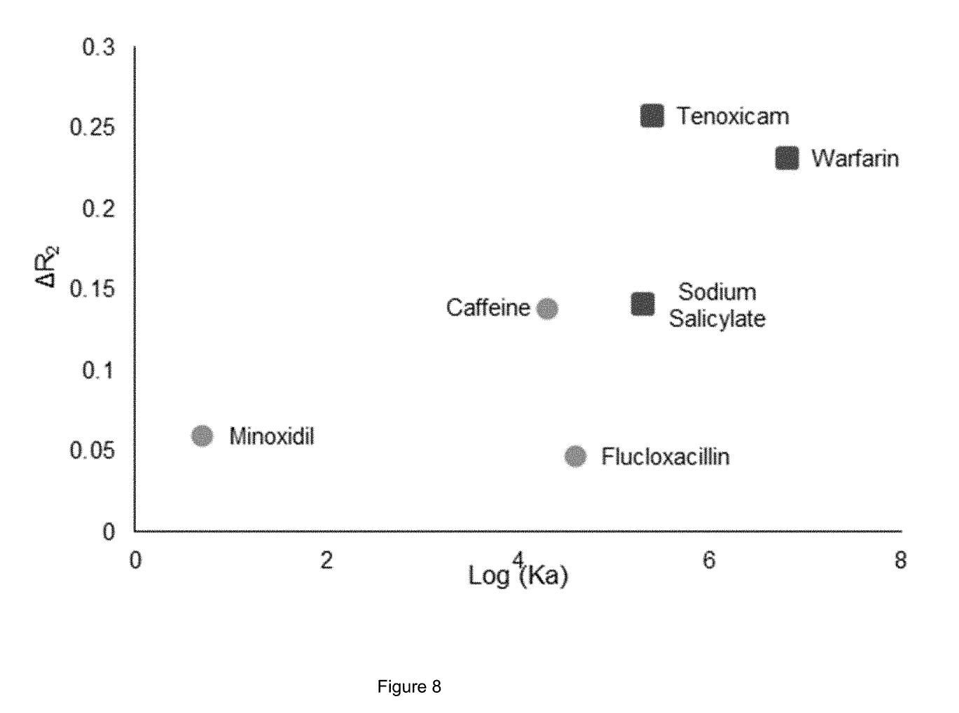

These data suggest that strongly binding drugs will decrease the bulk relaxation time of xenon more strongly than weakly binding drugs. Also, drugs that bind to site 1 tend to lower the relaxation time of xenon more than those that bind to site 2. This effect is seen in FIG. 8. FIG. 8 shows an example of a plot of the change in R₂ after 1 mM of a drug was added to 10 μM of BSA. Drugs that bind to site one tend to increase the R₂ of xenon more than other drugs. Drugs that bind to site 1 are shown as squares and drugs that bind to site 2 are shown as circles. Flucloxacillin and caffeine are the two outliers in this figure, with flucloxacillin affecting R₂ less than expected and caffeine affecting R₂ more than expected. This provides the capability to rapidly test small molecule drugs for their relative binding affinity to serum albumin, a task that could take a considerable amount of time in the past.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A method for measuring a compound's binding affinity for a protein, the method comprising:
providing a solution comprising the protein, the compound, and a hyperpolarized noble gas; and
measuring a magnetic resonance relaxation rate of the hyperpolarized noble gas in the solution comprising:
applying a static magnetic field to the solution;
applying a first radiofrequency pulse to the solution;
applying at least a second radiofrequency pulse to the solution, wherein the second radiofrequency pulse is out of phase with the first radiofrequency pulse; and
detecting a resonant response to the radiofrequency pulses.

2. The method of claim 1, further comprising repeating applying the second radiofrequency pulse, and detecting the resonant response.

3. The method of claim 1, further comprising repeating applying the second radiofrequency pulse a plurality of times separated by a time less than 400 ms, and detecting a plurality of resonant responses.

4. The method of claim 3, comprising determining the magnetic resonance relaxation rate from the plurality of resonant responses.

5. The method of claim 1, wherein the static magnetic field has a strength lower than 2 T or higher than 8 T.

6. The method of claim 1, wherein the first radiofrequency pulse is a 90 degree pulse.

7. The method of claim 1, wherein the first radiofrequency pulse is a pulse between 10 degrees and 45 degrees.

8. The method of claim 1, wherein the second radiofrequency pulse is a 180 degree pulse.

9. The method of claim 1, wherein the second radiofrequency pulse is a pulse between 10 degrees and 45 degrees.

10. The method of claim 9, wherein the second radiofrequency pulse is a 20 degree pulse.

11. The method of claim 1, where the protein is a blood protein.

12. The method of claim 1, where the hyperpolarized noble gas is ¹²⁹Xe or ³He.

13. The method of claim 1, wherein the solution comprises an anti-foaming agent.

14. The method of claim 1, wherein the magnetic resonance relaxation rate is measured using an alkali vapor magnetometer or a pick up coil.

15. The method of claim 1, wherein the magnetic resonance relaxation rate includes at least one of a longitudinal relaxation rate (T1) and a transverse relaxation rate (T2).

16. The method of claim 1, further comprising correlating the magnetic resonance relaxation rate with binding affinity.

17. The method of claim 1, further comprising generating a flow of hyperpolarized noble gas into the solution, and stopping the flow of hyperpolarized noble gas prior to measuring the magnetic resonance relaxation rate of the hyperpolarized noble gas in the solution.

18. A method of measuring the effects of different chemical environments on a compound's binding affinity for a protein, the method comprising:
providing a first solution comprising the protein, the compound, a first concentration of an environment altering agent, and a hyperpolarized noble gas;
measuring a first magnetic resonance relaxation rate of the hyperpolarized noble gas in the first solution;
providing a second solution comprising the protein, the compound, a second concentration of the environment altering agent, and the hyperpolarized noble gas; and
measuring a second magnetic relaxation rate of the hyperpolarized noble gas in the second solution.

19. The method of claim 18, wherein the second solution is obtained by adding an amount of the environment altering agent to the first solution.

20. An apparatus for determining a compound's binding affinity for a protein comprising:
a first syringe pump containing a first solution comprising the protein;
a second syringe pump containing a second solution comprising the protein and a compound to be tested;
a gas infusion cartridge, wherein outlets of the first and second syringe pumps are configured to permit injection of a mixture of the first and second solutions into the gas infusion cartridge; and
an NMR spectrometer, wherein an outlet of gas infusion cartridge is configured to provide the mixture to the NMR spectrometer.
